(19) United States
(12) Patent Application Publication
(10) Pub. No.: US 2026/0120994 A1
(43) Pub. Date: Apr. 30, 2026

(54) SPECTROSCOPY-BASED SAFETY SYSTEM FOR NUCLEAR REACTION DETECTION IN AN ION IMPLANTATION SYSTEM

(71) Applicant: Axcelis Technologies, Inc., Beverly, MA (US)

(72) Inventors: Peter DeRosa, Rockport, MA (US); Wilhelm Platow, Newburyport, MA (US); Kevin Wenzel, Belmont, MA (US)

(21) Appl. No.: 19/011,749

(22) Filed: Jan. 7, 2025

Related U.S. Application Data
(60) Provisional application No. 63/620,193, filed on Jan. 12, 2024.

(51) Int. Cl. H01J 37/317; H01J 37/16; H01J 37/244; H01J 37/30

(52) U.S. Cl. CPC H01J 37/3171; H01J 37/165; H01J 37/244; H01J 37/3007; H01J 2237/057

(57) ABSTRACT

An ion implantation system includes a spectroscopy-based safety system for nuclear reaction detection. A spectra analysis and safety system are disclosed herein. Associated methodology for use with the system includes processing data received from photon energy resolving spectrometers in order to identify detected photon energy, and alert the operator to the same and/or shutdown the system.

### REFERENCE TO RELATED APPLICATIONS

This application claims the benefit of U.S. Provisional Application Ser. No. 63/620,193 filed Jan. 12, 2024, entitled, “SPECTROSCOPY-BASED SAFETY SYSTEM FOR NUCLEAR REACTION DETECTION IN AN ION IMPLANTATION SYSTEM”, the contents of which are herein incorporated by reference in their entirety.

### FIELD

The present disclosure relates generally to ion implantation systems, and more particularly to monitoring for nuclear reactions in ion implantation systems.

### BACKGROUND

Ion implantation systems are utilized to dope a workpiece, such as a semiconductor wafer, with ions from an ion beam, to either produce n- or p-type doped material, or to form passivation layers during fabrication of an integrated circuit. Such beam treatment is often used to selectively implant the wafers with a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. When implanting ions into silicon wafers, ions generated from source materials such as antimony, arsenic, or phosphorus, for example, result in an “n-type” extrinsic material wafer, whereas a “p-type” extrinsic material wafer often results from ions generated with source materials such as boron, gallium, or indium. When implanting ions into silicon carbide (SiC) wafers, for example, nitrogen (n-dopant) and aluminum (p-dopant) are conventionally used as ion species. In addition, light ions, such as hydrogen or helium, are being used as implant species to reduce minority carrier lifetime, improve switching speed, and reduce switching losses in Insulated-Gate Bipolar Transistors (IGBT).

In an ion implanter, an ion source generates ions of desired atomic or molecular dopant species. These ions are extracted from the ion source by the ion extraction device, which are typically a set of electrodes that energize and direct the flow of ions from the ion source, forming an ion beam. Desired ions are separated from the ion beam in the mass analysis device, which is typically a magnetic dipole performing mass dispersion or separation of the extracted ion beam. The beam transport device, which is typically a vacuum system containing a series of focusing and acceleration/deceleration devices, transports the analyzed ion beam to the wafer processing device while maintaining desired properties of the ion beam. Finally, semiconductor wafers or other targets for implantation are transferred into and out of a wafer processing device via a wafer handling system, which may include one or more robotic arms, for placing a wafer to be treated in front of the analyzed ion beam and removing treated wafers from the ion implanter.

For many ion implantation systems, the physical size of the ion beam is smaller than a target workpiece, whereby the ion beam is scanned in one or more directions to adequately cover a surface of the target workpiece. Generally, an electrostatic or magnetic based beam scanner scans the ion beam in a fast scan direction and a mechanical device moves the target workpiece in a slow scan direction to provide sufficient coverage of the ion beam across the surface of the workpiece.

Ion implantation systems can produce unwanted beam strikes on interior parts of the system. This can cause particle emissions imparting ionizing radiation and breakdowns of the linings in certain chambers or the chamber walls themselves. Ion implantation systems are highly tuned instruments that require high precision, and, if not carefully tuned, at some point, an unwanted beam strike may occur. In addition, unwanted reactions from the beam can be caused if an incorrect material, e.g., a heavy metal, is mistakenly inserted into the system, for example inserted into the end chamber, or utilized as a Faraday cup, or as a liner. For example, if a titanium material is hit with hydrogen ion at energy above 800 keV, it will produce a fusion reaction with gamma-ray photon emissions.

### SUMMARY

The present disclosure provides a system and method for detecting and monitoring photon energy and ionizing radiation in an ion implantation system. In particular, this monitoring system can be used during operation of the ion implantation system to quickly shutdown the system if a threshold is exceeded. This improves the prevention of radiation exposure to operators and prevention of damage to equipment.

Accordingly, the following presents a simplified summary of the disclosure to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

In some aspects, the techniques described herein relate to an ion implantation system, including: an ion source that generates ions and produces an ion beam along a beamline, wherein the ions are selected from elements with an atomic number of 1 to 11; a mass analyzer positioned downstream of the ion source that generates a magnetic field; an ion accelerator downstream of the mass analyzer; a first photon energy resolving spectrometer associated with a component of the ion implantation system.

In some aspects, the techniques described herein relate to a method of conducting ion implantation operations including the operations of: exciting ions with an atomic number of 1 to 11 and accelerating the ions at an energy of 10 keV to 30 MeV; detecting photons at a first photon energy resolving spectrometer and transmitting a first signal to a processor; receiving at the processor the first signal from the first photon energy resolving spectrometer; and processing the first signal to determine a type of photon energy if a threshold is exceeded.

In some aspects, the techniques described herein relate to an ion implantation system, including: an ion source that generates ions and produces an ion beam along a beamline, wherein the ions are selected from elements with an atomic number of 11 or less; a mass analyzer positioned downstream of the ion source that generates a magnetic field; an ion accelerator downstream of the mass analyzer; a first photon energy resolving spectrometer associated with a first component of the ion implantation system; a second photon energy resolving spectrometer associated with a second component of the ion implantation system; a third photon energy resolving spectrometer associated with a third component of the ion implantation system; a processor that is configured to receive input signals from the first, second, and third photon energy resolving spectrometers; process the input signals to identify detected photon energy as known or unknown photon energy; and transmit an alert to a display and/or shutdown the ion implantation system if a threshold of unknown or particular known photon energy is identified. The processor is configured to process input signals from the first, second, and third photon energy resolving spectrometers to identify a source location of detected photon energy.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings. Furthermore, the features of the various embodiments and examples described herein may be combined with each other unless specifically noted otherwise.

### BRIEF DESCRIPTION OF THE DRAWINGS

FIG. 1 is a simplified top view illustrating an ion implantation system in accordance with an aspect of the present disclosure.

FIG. 2 is a cross-sectional view of an example of a portion of an ion implantation system in accordance with an aspect of the present disclosure.

FIG. 3 is a cross-sectional view of an example specialized liner 400.

FIG. 4 is a flowchart of an example method for operating an example ion implantation system including detecting high-energy photons in an ion implantation system, and processing the signal receiving therefrom.

FIG. 5 is an example flowchart of the ion implantation and spectrometer operations at a system level.

FIG. 6. is an example of a photon energy decay spectrum using calibration isotopes Cs-137 and Co-60. Each long hash on the horizontal axis indicates a gap of 1000 kEv from the next long hash and each long hash on the vertical axis indicates a gap of 20 counts/keV from the next long hash.

### DETAILED DESCRIPTION

In an example, a semiconductor manufacturing system includes an energy sensitive photon energy resolving spectrometer, such as a gamma ray detector associated with different locations in the system. The detector can be used to generate a spectroscopic fingerprint that can be matched to known samples of nuclear ion radiation. In addition, the system includes a controller that will shutdown the system if a threshold level of harmful nuclear radiation is detected.

As ion implantation systems are operated at higher energies with lighter species, there is a heightened risk of operators accidentally creating nuclear reactions in the liner or other materials in the beamline. This can be caused by operator mistuning of the system components and/or using an improper material in a particular location.

For example, the operation of the ion implantation system with high-energy beams has the possibility of eroding or sputtering away protective liners within the beam line. Liners are frequently used that run along a portion of the beamline in a chamber of the ion implantation system to prevent semiconductor wafers from being exposed to unwanted contaminants sputtered from the beamline walls (especially metals). In the case of high-energy beams, the liners can also be used to prevent nuclear reactions between light high-energy ion species (e.g., hydrogen) and other elements such as graphite or aluminum. Erosion of the liners that exposes undesired elements can cause unwanted nuclear reactions from beam line material collisions.

The ion implantation system fitted with a spectrometer in this invention disclosure uses a photon-energy resolving crystal detector, mounted with necessary electronics for signal processing and detection. The technology disclosed herein combines cutting-edge energy spectroscopy techniques with high-energy low atomic weight ion implantation systems.

In an example, the detection system is mounted near multiple erosion sites, and with constant monitoring, detection of unwanted nuclear reactions can be resolved and identified quickly, identifying the possibility of a liner/beam line material that has failed due to an ion beam strike. Unique liners can be inserted under beam line strike surfaces to produce unique photon “fingerprint” signature for detection ease. Additionally, if an incorrect workpiece, e.g., a metal wafer, instead of a silicon wafer, or a silicon wafer with devices containing low atomic weight (low Z) elements, is implanted, this can also be quickly detected with the spectrometer detector system.

Semiconductor manufacturing systems, such as, for example, ion implantation systems, include chambers that are under vacuum and are being bombarded by particle streams or other operations during use. An advantage of using high-energy photon energy resolving spectrometers is that difficulties in monitoring the formation of internal radiation sources are avoided since such high-energy photons, e.g., gamma rays and x-rays are sufficiently energetic to pass through the walls of the system.

The present disclosure is directed generally toward various apparatuses, systems, and methods associated with implantation of ions into a workpiece or other semiconductor manufacturing processes. More specifically, the present disclosure is directed to a semiconductor manufacturing system with a high-energy photon energy resolving spectrometer and a method for detecting high-energy photons and alerting and shutting down the system when threshold conditions are reached.

Accordingly, the technology is described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the technology described herein. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as exemplary only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components for all embodiments encompassed by this disclosure.

It is also to be understood that in the following description, any direct connection or coupling between functional blocks, devices, components, or other physical or functional units shown in the drawings or described herein could also be implemented by an indirect connection or coupling. Furthermore, it is to be appreciated that functional blocks or units shown in the drawings may be implemented as separate features or components in one embodiment, and may also or alternatively be fully or partially implemented in a common feature or component in another embodiment.

The terms workpiece and workpiece support are used herein with recognition that a workpiece, such as, a silicon wafer, will be utilized in operation, but a workpiece support is used to hold and position the workpiece. Furthermore, ion implantation systems may be produced with workpiece supports that are configured to hold workpieces, but are not typically manufactured or sold with workpieces. Thus, discussion of a workpiece and how the beam or components of the ion implantation systems disclosed herein relate to a workpiece should also be understood to be disclosed in terms of the workpiece support. The term “workpiece target” is used herein to mean either a workpiece if the workpiece is in place on the workpiece support or the location where a workpiece is configured to be held by a workpiece support.

In ion implantation, dopant atoms/molecules are ionized and isolated, sometimes accelerated or decelerated, formed into a beam, and swept across a workpiece or wafer. The dopant ions physically bombard the workpiece, enter the surface, and typically come to rest below the workpiece surface in the crystalline lattice structure thereof. In light ion, high-energy ion implantation, the ions are selected from elements with an atomic number of 11 or less, such as 7 to 2, or 3 to 1. For example, ions such as H, He, Li, Be, and B, may be generated in the ion source. In an example of higher mass beam species, C, N, O, F, Ne, P, and As can also be generated in the ion source. These ions are accelerated to high energy states, such as, at or above 300 keV, for example, 400 keV to 15 MeV, 500 keV to 10 MeV, or 1 MeV to 5 MeV.

Accelerator systems that conduct higher energy beams, such as, the acceleration of ion beams above 400 keV, may utilize a LINAC structure using resonators, cavities, and/or RF gap style systems; they may also utilize a tandem acceleration scheme or radio frequency quadrupole (RFQ) acceleration. The use and implementation of these devices implements energy resolving slits or ERS, usually coupled with magnets, to isolate the final energy exiting the acceleration structure of the machine. The combination of a LINAC block with an ERS and magnet for energy resolving is often used in high energy systems.

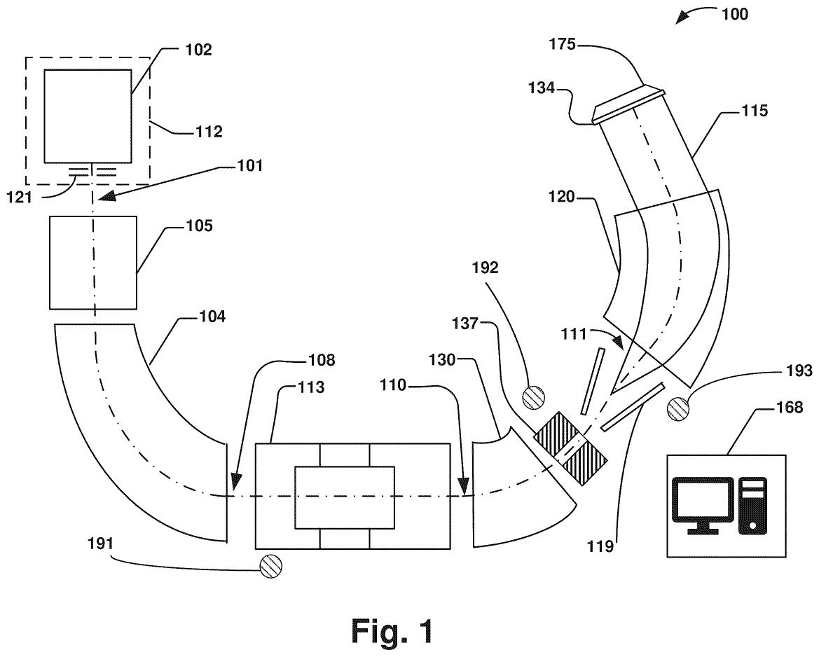

Referring now to the figures, in accordance with one exemplary aspect of the present disclosure, FIG. 1 illustrates an exemplary hybrid parallel scan single wafer ion implantation system 100. The ion implantation system 100 is also referred to as a post acceleration implanter, since a main accelerator 113 is placed after a mass analyzer 104 and before an energy filter 130. Ion implantation systems 100 of this type often (as shown) have the energy filter 130 after (i.e., further from the ion source 102 along the beamline) the main accelerator 113 to remove unwanted energy spectrum in the output of the main accelerator 113.

In this exemplary ion implantation system 100, an ion beam 101 generated from the ion source 102 is accelerated by an optional pre-mass analyzer accelerator 105 that is positioned before the mass analyzer 104 to generate an accelerated and analyzed ion beam 108. Downstream, the accelerated and analyzed ion beam 108 may be further accelerated in the main accelerator 113 by a plurality of accelerator stages therein. For example, the accelerator stages may comprise resonators (as with an RF accelerator) respectively to generate RF acceleration fields therein and output an accelerated ion beam 110 that has been further accelerated. After passing through the energy filter 130, the filtered ion beam 111 goes through a beam scanner 119 and then through an angle corrector lens 120 to convert the filtered ion beam 111 into a parallel shifted ion beam 115.

A workpiece 134 is moved orthogonal (shown as moving in and out of the paper) to the parallel shifted ion beam 115 in the hybrid scan scheme to irradiate the entire surface of the workpiece 134 uniformly. Other types of scanning can also be used with the monitoring and associated technology described herein. As stated above, various aspects of the present disclosure may be implemented in association with any type of ion implantation system, including, but not limited to the exemplary ion implantation system 100 of FIG. 1.

The components of FIG. 1 are now described in more detail. The source chamber assembly 112 comprises the ion source 102 and an ion extraction electrode assembly 121 to extract and accelerate ions to an intermediate energy. To generate the ions, a gas of a dopant material to be ionized is located within an ion generation chamber (not shown) of the ion source 102. Other sources and forms of dopants can be used, e.g., the dopant can be sputtered (e.g., aluminum nitride) or introduced as a vapor (e.g., aluminum chloride). The dopant gas can, for example, be fed into the source chamber assembly 112 from a gas source (not shown). It will be appreciated that one or more suitable mechanisms (not shown) can be used to excite free electrons, such as, for example, RF or microwave excitation sources, electron beam injection sources, electromagnetic sources and/or a cathode which creates an arc discharge within the chamber. The excited electrons collide with the dopant gas molecules and ions are generated thereby. Typically, positive ions are generated although the disclosure herein is applicable to systems wherein negative ions are generated as well.

The ions are controllably extracted through a slit in the ion extraction electrode assembly 121. The ion extraction electrode assembly 121 comprises a plurality of extraction and/or suppression electrodes. The ion extraction electrode assembly 121 can include, for example, a separate extraction power supply (not shown) to bias the extraction and/or suppression electrodes to accelerate the ions from the source chamber assembly 112. It can be appreciated that since the ion beam 101 comprises like-charged particles, the beam may have a tendency to expand radially outwardly as the like charged particles repel one another. It can also be appreciated that beam expansion can be exacerbated in low energy, high current (high perveance) beams where many like charged particles (e.g., high current) are moving in the same direction relatively slowly (e.g., low energy) such that there is an abundance of repulsive forces among the particles, but little particle momentum to keep the particles moving in the direction of the beam path. Accordingly, the ion extraction electrode assembly 121 is generally configured so that the beam is extracted at a high-energy so that the beam does not expand unduly (e.g., so that the particles have sufficient momentum to overcome repulsive forces that can lead to beam expansion), which would lead to beam current loss.

The pre-analyzer accelerator 105 further accelerates the ions and is an optional component, which may be unneeded for some operations.

The mass analyzer 104 generates a magnetic field according to a selected charge-to-mass ratio and performs an angle adjustment to the ion beam 101. The mass analyzer 104, in this example, is configured to bend the ion beam 101 at about a ninety-degree angle and comprises one or more magnets (not shown) that serve to establish a (dipole) magnetic field therein. As the ion beam 101 enters the mass analyzer 104, it is correspondingly bent by the magnetic field such that ions of an inappropriate charge-to-mass ratio are rejected. More particularly, ions having too great or too small a charge-to-mass ratio are deflected into side walls of the mass analyzer 104. In this manner, the mass analyzer 104 mainly allows those ions in the ion beam 101 which have the desired charge-to-mass ratio to pass there-through and in an example exit through a mass resolving aperture, which can further adjust the ion beam 101. It will be appreciated that collisions of the ion beam 101 with other particles in the ion implantation system 100 can degrade beam integrity. Accordingly, one or more pumps (not shown) may be included to evacuate parts of the system, for example, the mass analyzer 104.

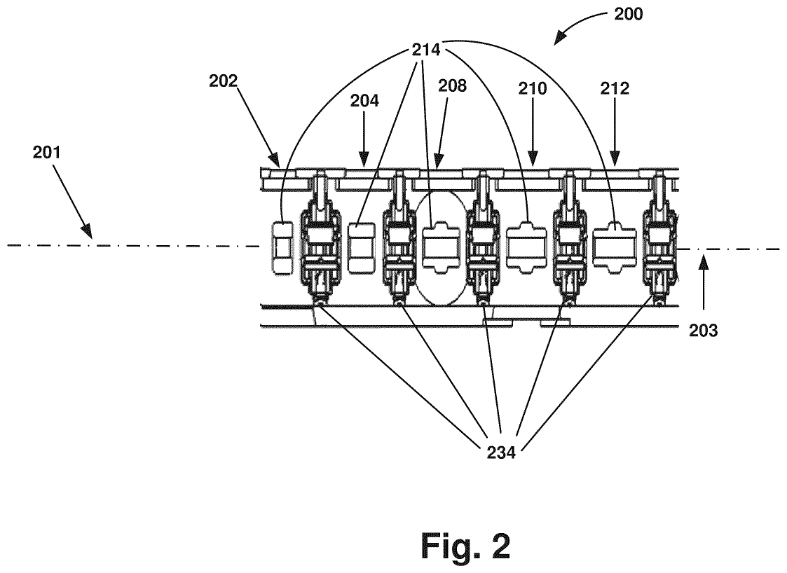

The main accelerator 113 accelerates the ions to a higher energy, and, for example, can be an RF linear particle accelerator (LINAC), in which ions are accelerated repeatedly by an RF field, or a DC accelerator (e.g., a tandem electrostatic accelerator), which accelerates ions with a stationary DC high voltage. The main accelerator 113 is described further with respect to FIG. 2 below.

After the accelerated ion beam 110 exits the main accelerator 113, it is further conditioned by an energy resolving slit (ERS) 137. The ERS 137 is a structure and method that collimates the energy distribution of transported accelerated particles exiting a LINAC block assembly. The energy resolution of a given beam can be tuned by how wide the slit is in the presence of the beam and by what amplitudes and phases are selected. Often coupled with a dipole bending magnet, where the trajectory of the higher energy ions will have less curvature than lower energy ions within a given accelerated beam. Using this, one can introduce an acceptance to make the energy distribution a fixed value. For example, the width of a “standard” ERS could be an energy distribution/resolution of +/−5% of the desired accelerated beam energy, to which the operator could change that resolution to 10% or 0.05% depending on the relative slit width of the allowed beam as it comes out of dipole magnet from the LINAC.

The beam scanner 119, either electrostatically or electromagnetically scans the accelerated ion beam 110, typically left to right, into the angle corrector lens 120, which converts the filtered ion beam 111 into the parallel shifted ion beam 115.

The angle corrector lens 120 causes the filtered ion beam 111 to alter its path such that the ion beam travels parallel to a beam axis regardless of the scan angle. As a result, the implantation angle is relatively uniform across the workpiece 134 and normalized to eliminate vertical deviations of the beam, making it almost horizontal moving towards its final destination. The angle corrector lens 120 can be an electromagnetic magnet as shown, but can also be electrostatic, for example. The final parallel shifted ion beam 115 that results from the angle corrector lens 120 is directed onto the workpiece 134.

The workpiece 134, if not present, occupies the same space as a workpiece target (as further explained above) and is held by a workpiece support 175, which can be housed in a process chamber or end station (not shown). It is appreciated that different types of end stations and workpiece supports 175 may be employed in the ion implantation system 100. For example, a “batch” type end station can simultaneously support multiple workpieces 134 on a rotating workpiece support structure, wherein the workpieces are rotated through the path of the ion beam 115 (also called a beamline) until all the workpieces are completely implanted. Such a “batch” type implanter does not require a scanner and corrector lens. A “serial” type end station, on the other hand, supports a single workpiece 134 along the path of the ion beam 115 for implantation, wherein multiple workpieces are implanted one at a time in serial fashion, with each workpiece being completely implanted before implantation of the next workpiece begins. In hybrid systems, the workpiece 134 may be mechanically translated in a first direction (the y-direction or so-called “slow scan” direction) while the ion beam 115 is scanned in a second direction (the x-direction or so-called “fast scan” direction) to impart the parallel shifted ion beam 115 over the entire workpiece 134.

FIG. 2 illustrates one example of a portion of an ion implantation system in accordance with one aspect of the disclosure. An accelerator 200, which can be the main accelerator 113 of FIG. 1, can comprise an RF accelerator, which is illustrated in FIG. 2 as one example of an embodiment, and can comprise a number of accelerator stages (e.g., 202, 204, 208, 210, and 212). The accelerator stages 202, 204, 208, 210, and 212 can respectively comprise at least one accelerator electrode 214 which is driven by an RF resonator, for example, for generating an RF accelerating field on both sides (not shown). An ion beam 201 of charged particles with a charge state (e.g., a net electrical charge or a valence) can pass through apertures of the accelerator electrodes 214 in succession.

Beam focusing can be provided by lenses 234 (e.g., electrostatic or magnetic quadrupole) incorporated within the accelerator 200. In one embodiment, the accelerator 200 can accelerate charged ions to a kinetic energy level at or exceeding 10 keV or at or exceeding 300 keV when the accelerated beam exits the accelerator 200. In an example, a lens 234 is included in each accelerator stage (202, 204, 208, 210, and 212).

There is not one particular accelerator or type of LINAC that the present disclosure is confined to. The number of stages is not confined to the illustration of FIG. 2, and can be, for example, 1 to 50 accelerator stages, such as 2 to 10, or 3 to 6. In addition, the accelerator could be a tandem accelerator or RFQ.

A control system 168 (also called a controller) is further provided to control, communicate with, and/or adjust the ion source 102, the pre-analyzer accelerator 105, the mass analyzer 104, the main accelerator 113, the ERS 137, the beam scanner 119, and the angle corrector lens 120. While connections are not shown in FIG. 1, the controller is normally coupled by a communications cable to the various components it controls.

The control system 168 can also be coupled to one or more power supplies for the components. The control system 168 may also be coupled to the one or more photon energy resolving spectrometers (e.g., photon energy resolving spectrometers 191, 192, 193) associated with the ion implantation system 100.

The control system 168 may comprise a computer with a processor and data storage, and may be operable to take measurement values of characteristics of the ion beam and adjust parameters accordingly. It can also be configured, for example, by software or hardware to receive signals from the photon energy resolving spectrometers 191, 192, 193 and process them to produce reports and alerts to an operator via a display. In addition, the control system 168 can be configured to process the signals from the photon energy resolving spectrometers 191, 192, 193 and make determinations of whether threshold levels of unknown radiation or known and unwanted radiation are present as disclosed further below. The control system 168 can also control a power supply or other components to shut down the beamline operations in the event that threshold levels of radiation are reached.

The ion implantation system 100 includes multiple high-energy photon energy resolving spectrometers 191, 192, 193. For example, two to six, or three to five detectors can be utilized in the ion implantation system 100. In an embodiment, a single detector can also be used.

A known or unknown radiation determination can be made by comparing one or more signal spectra to a database of known safe and unsafe X-ray or gamma-ray signatures, e.g., the National Nuclear Materials and Signatures Database. Furthermore, the signals from the photon energy resolving spectrometers 191, 192, 193 can be processed to determine where the high energy emissions are originating from in the ion implantation system 100. The photon energy detected by the photon energy resolving spectrometers can include photons in the X-ray range such as, for example, energies of 100 eV to 100 keV. Additionally, for photons in the gamma ray energy range, 1 keV to 20 MeV, such as 10 keV to 15 MeV, or 50 keV to 5 MeV is sufficient for most applications.

With multiple photon energy resolving spectrometers, the photon energy resolving spectrometers can be spaced out and in proximity to the most likely areas of the ion implantation system to produce high-energy radiation, e.g., X-rays or gamma rays. In an example, the photon energy resolving spectrometers are spaced (one from another one) by at least 1 foot, such as 1.5 feet to 30 feet, 2 feet to 15 feet, or 2.5 feet to 5 feet. In an embodiment, each photon energy resolving spectrometer of the system is spaced at least 1 foot, such as 1.5 feet to 30 feet, 2 feet to 15 feet, or 2.5 feet to 5 feet from any other photon energy resolving spectrometer in the system.

Because the high-energy radiation of concern is not contained by the walls or chamber linings of the ion implantation system, the photon energy resolving spectrometers can be located outside the walls of the system and still be associated with the photon energy of interest. However, the photon energy resolving spectrometers should be placed near the outer walls of a component or chamber of the system, such as, for example, immediately touching the outside wall of a chamber of the system to 3 feet from the outer wall of a chamber of the system, 0.1 to 2.5 feet, or 0.5 to 1 foot from the outer wall of a chamber of the system.

At various locations in the ion implantation system 100, different materials have the potential to be sputtered away following a bombardment by a particle beam strike. The three locations seen in FIG. 1 show the photon energy resolving spectrometer near the LINAC main accelerator 113, the ERS 137, and the beam scanner 119. In an example, a first, second, and third photon energy resolving spectrometers 191, 192, 193, are located outside and adjacent to (either beside, above, or below) the beam scanner 119, the LINAC main accelerator 113, and the ERS 137 (respectively). In an example, each photon energy resolving spectrometer is spaced closer to the LINAC main accelerator 113, the ERS 137, or the beam scanner 119 than any other component of the system. In another example, a photon energy resolving spectrometer is located near an end terminal where a workpiece 134 and workpiece support 175 may be present. In another example, a photon energy resolving spectrometer is located near a Faraday cup, dose cup, bending magnets, or another structure that may be impacted by the beam or cause a deflection.

The multiple photon energy resolving spectrometers 191, 192, 193 are coupled to a control system 168 that is configured to process through a processor and data storage, the incoming signals from the photon energy resolving spectrometers. By the intensity of the signal and knowing the location of the photon energy resolving spectrometers, the controller is configured to determine a location where the system is experiencing a radiation event (detected photon energy). In addition, the controller can interpret the signal from the photon energy resolving spectrometer to determine a type of radiation, e.g., X-ray or gamma ray, or particular spectra data that match known spectra data. The controller can cause this information to be stored in data storage and provide an operator with this information via a graphical user interface on a display. In addition, the controller can cause the system to shut down if a threshold level of radiation is detected, as described further below.

While the photon energy resolving spectrometer and shutdown control disclosed herein is primarily described for use in ion implantation systems, it can also be used in other devices such as high-energy particle accelerators.

In an example, the photon energy resolving spectrometer is a solid-state scintillator-type spectrometer. Scintillators are materials that emit flashes or pulses of light when they interact with ionizing radiation. Scintillator crystals are used in radiation detectors for gamma-rays, X-rays, cosmic rays, and particles characterized by an energy level of greater than about 1 keV.

A spectrometer includes the scintillating crystal (or other scintillator) with an element for detecting the light produced by the crystal when it interacts, or “scintillates,” when exposed to a source of radiation, e.g., a photodetector. The photo-detector produces an electrical signal proportional to the intensity of the scintillation (or light pulses received from the scintillator material). The electrical signal is then processed in various ways to provide data on the radiation.

In an example, the photon energy resolving spectrometer used herein may be a scintillating crystal device, such as, a NaI crystal that is doped with thallium, germanium, cesium bromide, or lanthanum bromide.

In an example, specialized liners may be placed in chambers where beam strikes are most likely, for example, the LINAC accelerator 113, ERS 137, and beam scanner 119. Although it is normal for protective liners to be placed inside the beam line to prevent unwanted nuclear reactions, the specialized additional interior liner underneath the beam strike protector plates can be used instead of these or in addition to these. In conjunction with the photon energy resolving spectrometers the specialized liner provides additional analysis and alerting abilities prior to any unwanted nuclear reactions.

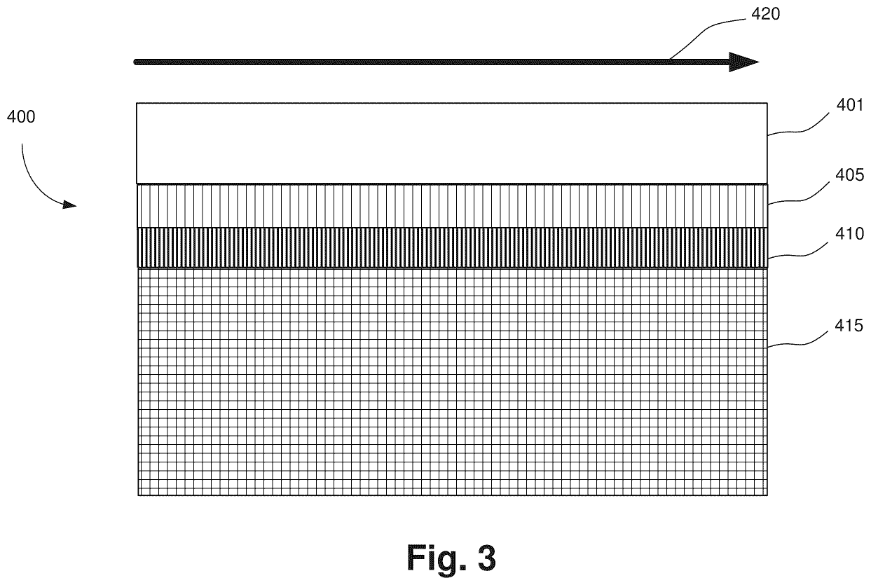

FIG. 3 is a cross-sectional view of an example specialized liner 400. The specialized liner 400 could be used to coat a surface 415 of a component along the ion beam 420. For example, if dipole bending magnet poles, typically made of soft magnetic steel, are the surface 415, these typically have a nickel coating 410 on top of the surface. (Other surfaces 415 will not have a nickel coating on top.) In FIG. 3, on top of the nickel coating 410 is a film 405. (In other example surfaces 415, the nickel layer is absent, and the film 405 directly overlays the surface 415.) The film 405 may comprise low molecular weight species such as graphite, B, or an element having an atomic number Z, wherein 3<Z<72, such as 4<Z<30, or 5<Z<15. The top shielding layer 401 overlaying the film 405 may be a layer comprising a high Z (high atomic number) element, such as 72≤Z≤83. The specialized liner is distinguished from typical graphite liners, which do not provide the detection and protection functionalities.

In an example operation, an errant strike of the ion beam 420 would only strike the top shielding layer 401, such that the nickel coating 410 or surface 415 is not struck. If the top shielding layer 401 is penetrated with the beam, the film 405 may be struck that comprises graphite, Be, and/or B or other beam species will be struck. This will produce a unique photon energy emission spectrum. The photon energy spectrometer and the controller will be configured to identify within a short window of time that the film 405 has been struck. An alarm can then be provided by way of the processor and a display that a portion of the top shielding layer 401 has sputtered away.

In an embodiment, both the top shielding layer 401 and the film 405 will not generate hazardous radiation if struck by the beam, so long as a threshold level is not reached. For example, the film 405 may generate photon energy such as X-rays or less hazardous gamma rays that can be detected by the photon energy resolving spectrometer. Such radiation may not be harmful in a short term, and may provide an operator with sufficient time to address the problem and shut down the system before harm is done. In an embodiment, the beamline will automatically be shut down if any radiation signature is detected that is indicative of a layer of the liner being impacted by the beam.

The specialized liner material of the film 405 should be selected based on the ion source and/or particle beam energy, because the exact decay nature of the nuclear reactions that are produced from a beam strike are determined by the quantum mechanical properties of the beam and the liner. Changing the beam species or liner combinations changes the nature and energy of the photon decay signatures. The kinetic energy of the particle beam also determines photon decay probabilities. Thus, if the ion source/beam species or the particle velocity is changed, this information should be input to the system, notifying the controller to look for different photon decay signatures.

In an example, the controller will receive input of the ion source or beam material composition, the energy of the beam, and the liner type or types. The controller processes this information along with the data from the photon energy resolving spectrometers with data storage of known and unknown radiation signatures to analyze and determine. For example, different liner materials can be employed to identify different locations in the beamline, which would be easily identifiable due to the characteristic photon spectrum associated with various nuclear reactions.

This system can also be used to determine if the wrong type of wafer is being implanted. The prompt and decay radiation of activated isotopes in the wafer can be identified using the same spectroscopy techniques.

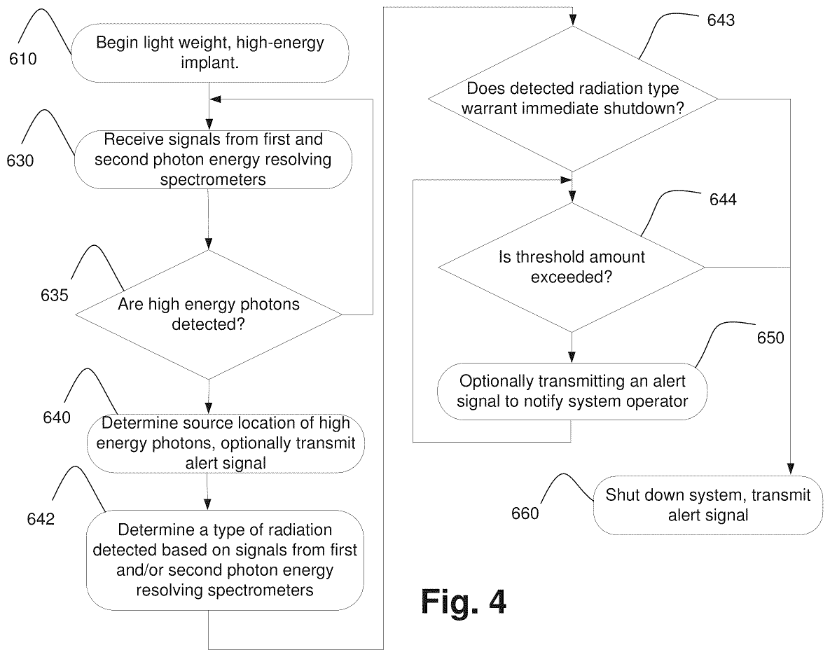

In reference now to FIG. 4, an exemplary methodology associated with the photon energy resolving spectrometers used in the ion implantation system will be further described. FIG. 4 is a flowchart of an example method for detecting high-energy photons in an ion implantation system, processing the signal received therefrom, and operating the ion implantation system.

At operation 610, ion implantation operations are conducted, such as those described above in a system such as shown in FIG. 1. In particular, light ion/high-energy ion implantation is conducted, which may be conducted by exciting ions with an atomic number of 1 to 11 and accelerating the ions at an energy of 300 keV to 20 MeV. The system and methods used herein can also be conducted with ions being accelerated at 10 keV to 30 MeV.

At operation 630 the processor receives the first and second signals that are transmitted from first and second photon energy resolving spectrometers. The signals can be transmitted and received through wired or wireless connections, but wired connections may provide better reliability.

At operation 635 the processor determines whether high energy photons are detected by analyzing the signal from the first and second photon energy resolving spectrometers. This can involve a first level determination if any high energy photons have been detected. This process continues until high energy photons are detected.

At operation 640 the first signal and second signal are processed to determine a source location of the detected photons. This can be done when the processor compares information as to the location of the photon energy resolving spectrometers and the levels of photon energy detected at each detector. Location data may be provided to the processor by storing coordinate (x, y, and optionally z) values in data storage of the photon energy resolving spectrometers. The location of the various components of the ion implantation system may also be input to data storage accessible to the processor in coordinate form. Alternatively, location information can be provided in the form of proximity of the photon energy resolving spectrometers to various components of the ion implantation system.

At operation 642, the first signal and/or second signal are processed to determine a type of the detected photon energy. This can be done by comparing the detected spectra data with known spectra of selected types of photon energy.

At operation 643, a determination is made on whether the radiation type warrants immediate shutdown. This may be based on a determination that the detected data matches a known (e.g., stored and accessible to a processor of the system in memory storage) photon energy spectra to a certain level of certainty. The determination may also be a determination that the detected data does not match a known photon energy spectra and is thus unknown. Optionally, an alert signal may be immediately transmitted to a display and/or the system shut down (operation 660) once this determination is made.

At operation 644, the first signal and second signal are processed to determine whether a threshold level of photon energy is exceeded. The threshold may be some level that has been designated as dangerous over a certain period of time, or a lower level.

Then, if the threshold is determined to be exceeded, a signal will be transmitted to shut down the system, and at operation 660 the system is shut down. By shut down, it is meant that the beamline operations cease such that the beam impacts causing the detected photon energy stop. In an example system, the beamline operations are shut down immediately and automatically. However, in some situations, such as if the threshold is set lower than a hazardous level, an alert may be triggered and provided to an operator at 650, for example, through a display. The operator may then have an opportunity to shut down the operation manually, and in an example operation, the system may be automatically triggered to shut down if no further input is received from the operator within a certain time after the first alert is transmitted, and/or if the detectors continue to identify the threshold being exceeded.

At operation 660 one or more alert signals may be transmitted to a display or some other alerting device. These signals include an identification of the spectra as a certain known type or an unknown type, a display of the detected spectra data, the location of the detected photon energy with respect to the ion implantation system and/or the likely component where the beam strike is taking effect, information identifying a layer of the liner that is being impacted, a total level and/or as the level relates to the threshold, and a time to imminent shutdown.

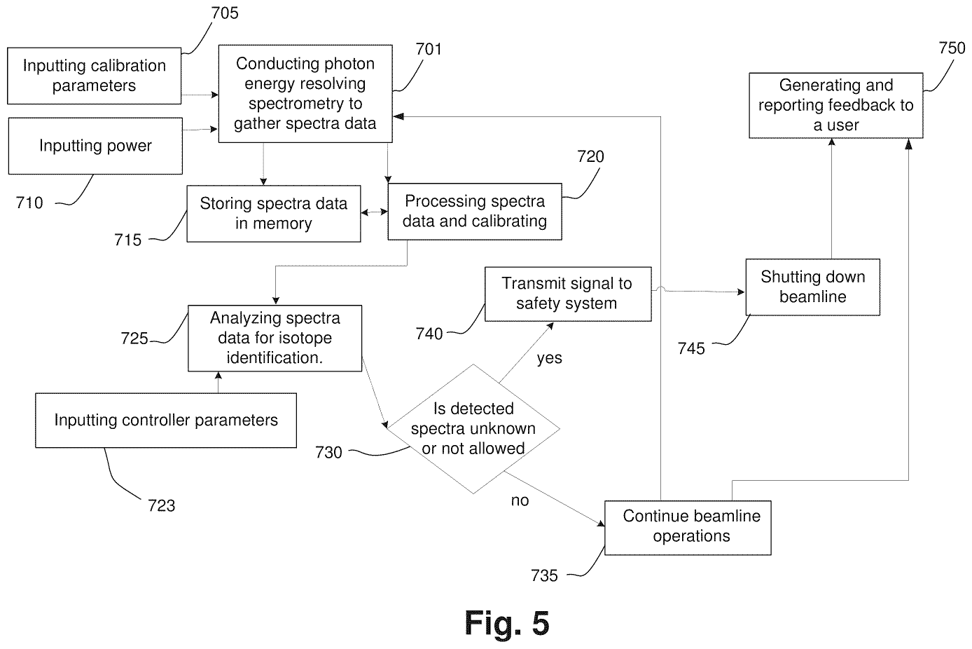

FIG. 5 is a flow diagram of the spectrometer and ion implantation operations at a system level. FIG. 5 and the discussion below is a related and in some cases a more detailed disclosure of operations also discussed in FIG. 4 above.

In FIG. 5, the photon energy resolving spectrometer 701 runs with power input 710 and input parameters 705. The data is then stored in memory 715 and processing of the data with calibration parameters is performed 720. Raw data or the processed and calibrated data can be stored in memory and accessed by a processor in the processing data and calibrating step 720. The photon energy resolving spectrometer 701 can include memory and a processor physically coupled to it or the photon energy resolving spectrometer 701 can transmit the data to a remote computing device that includes the memory and processor. The photon energy resolving spectrometer 701 can be one, at least one, multiple, or all photon energy resolving spectrometers.

The method continues by analyzing the calibrated data for identification of the reacted species 725 received from the photon energy resolving spectrometer by a computer processor. The calibrated spectra data is compared to known standards stored in memory. Controller parameters are input 723 to provide information about the ion implantation system. In an example, the controller will receive input parameters of the ion source or beam material composition, the energy of the beam, and the liner type or liner types if multiple liners are present in the system. The controller processes this information along with the data from the photon energy resolving spectrometers with data storage of known and unknown radiation signatures to analyze and determine the isotope or isotopes present in the spectra.

Based on the analyzed data, the processor then determines if an unknown or not allowed photon radiation source is present in the calibrated data 730. If the answer is no, then beamline operations continue 735. Optionally, if the determination is no, feedback will be generated and reported to a user, e.g., through a display 750. However, if the determination is yes, then the processor will send a signal to the safety system 740.

A not allowed photon radiation source may be, for example, any source of radiation that is either not identified or is at or above 100 keV in energy. For example, 511 keV photons could be identified as evidence of decaying radioisotopes via beta decay. Another example, of a not allowed photon radiation source, may be one that would be expected to be generated from beam strike on a layer of the liner, such as, the specialized layer disclosed herein.

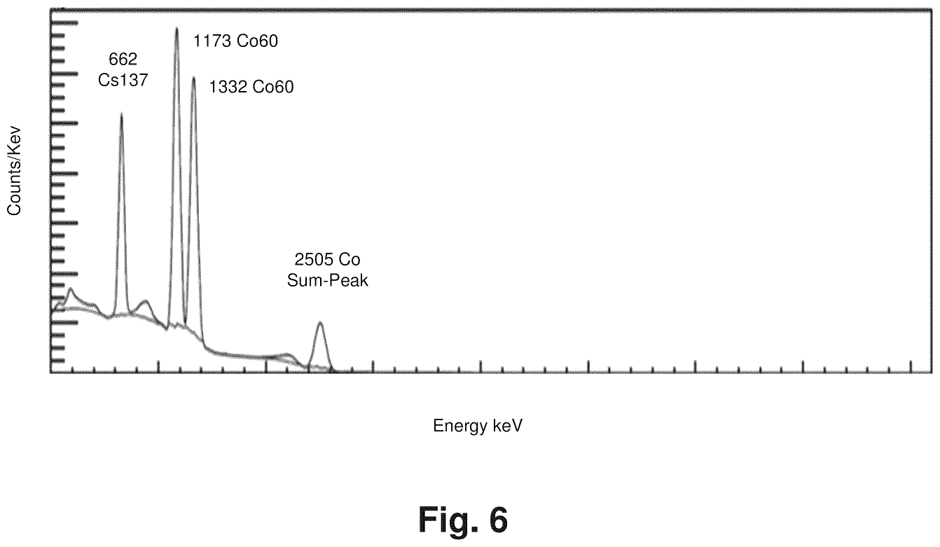

An example of a photon energy spectrometer output spectrum for reference can be seen in FIG. 6. The four peaks seen in the energy spectrum are a “fingerprint” of Cs137 which produces a 662 keV gamma-ray, Co-60 which produces a 1173 and 1332 keV gamma ray, and the summation peak of both Co-60 photon energies due to the energy integration time overlap of the recording spectrometer. The baseline in the photon spectrum represents the Compton scattering background estimation for the detection of these events. This photon signature can be used for calibration of the detectors or as a stored known spectrum for identifying detected isotopes in real time. Each liner and beam species combination will result in a similar spectrum, which can be energy calibrated prior to use, and therefore the determination of known peaks from the additional liner can be identified quickly.

In an example, throughout the process the identification system, which would be integrated into the central safety system of the accelerator, will be refreshing and pinging the processor for results during beam operations. The identification system would be able to control an interlock safety integrated system, essentially limiting access to the inside of the accelerator until a specified amount of time or the radiation source has decayed beyond detection and/or to background levels. If there is an unknown or not allowed spectral identification, then the beamline will be forced to shut down at 745, e.g., by putting a Faraday/beam blocking module in the beam path upstream of the radiation source. An example of this would be if the source is found after the LINAC module, a Faraday cup before the LINAC would be activated, shutting down the beam to that section of the beam path.

In an example method, the beamline operation will continue unless there is an affirmative identification of an unknown or unallowed spectral identification at a preset threshold. In another example method, the beamline operation will stop unless all detected spectral signatures are known and on a safe list or are not above a threshold. Whereas the threshold would be defined by the safety limit of the given location of the beam line. The threshold could be, for example, 100 or more counts, such as 200 or more, or 300 or more counts within a specific photon energy range.

In an example method, if the safety system shuts down the beamline operations, it will also generate and report feedback to the user, e.g., through a display 750. In an embodiment, the system will provide a constant monitoring display in real-time for one, multiple, or all of the photon energy resolving spectrometer 701 present within the system. For example, the display could be akin to an oscilloscope, wherein the logging/captured spectrum would form in live time. This could be a histogram of amplitudes of record charge signals that translate roughly to the energy of the photon.

Upon a beam interaction, the detected prompt radiation and possible decay radiation from the activated materials will be used to analyze radiation hazards during and after operation of the ion implanter. Thus, in an example, detection/analysis operations will continue even after the beamline operations are shut down to assess any lingering hazard of decay radiation.

Although the disclosure has been shown and described with respect to a certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including any reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes,” “including,” “has,” “having,” and variants thereof are used in either the detailed description or the claims, these terms are intended to be inclusive in a manner similar to the term “comprising.”

What is claimed is:

1. An ion implantation system, comprising:
an ion source that generates ions and produces an ion beam along a beamline, wherein the ions are selected from elements with an atomic number of 1 to 11;
a mass analyzer positioned downstream of the ion source that generates a magnetic field;
an ion accelerator downstream of the mass analyzer; and
a first photon energy resolving spectrometer associated with a component of the ion implantation system.

2. The ion implantation system of claim 1, wherein the ions comprise H ions, He ions, or both.

3. The ion implantation system of claim 1, further comprising a second photon energy resolving spectrometer associated with a different component of the ion implantation system and spaced away from the first photon energy resolving spectrometer by at least 1 foot.

4. The ion implantation system of claim 1, wherein the ion accelerator is configured to accelerate ions to an energy of 10 keV to 30 MeV.

5. The ion implantation system of claim 1, wherein the first photon energy resolving spectrometer associated with the component of the ion implantation system is touching an outside wall of a chamber of the ion implantation system or within 1 foot of an outside wall of the chamber of the ion implantation system.

6. The ion implantation system of claim 1, wherein the first photon energy resolving spectrometer is outside and adjacent to a beam scanner, the ion accelerator, or an energy resolving slit.

7. The ion implantation system of claim 1, further comprising a liner that runs along a portion of the beamline in a chamber of the ion implantation system, the liner comprising a film including a material selected from the group consisting of: graphite, or an element having an atomic number Z, wherein 3<Z<72.

8. The ion implantation system of claim 1, further comprising a liner that runs along a portion of the beamline in a chamber of the ion implantation system, the liner comprising a top shielding layer, the top shielding layer comprising an element with an atomic number Z, wherein Z is 72≤Z≤83.

9. The ion implantation system of claim 8, the liner further comprising a film including a material selected from the group consisting of: graphite, or an element having an atomic number Z, wherein 3<Z<72, wherein the top shielding layer overlays the film.

10. The ion implantation system of claim 1, further comprising a processor that is configured to receive input signals from the photon energy resolving spectrometer; process the input signals to identify detected photon energy as known or unknown; and transmit an alert to a display and/or shutdown the ion implantation system if a threshold of unknown or particular known photon energy is identified.

11. The ion implantation system of claim 10, further comprising a second photon energy resolving spectrometer, wherein the processor is configured to process input from the first photon energy resolving spectrometer and the second photon energy resolving spectrometer to identify a source location of detected photon energy.

12. The ion implantation system of claim 1, further comprising a display that is configured to transmit an alert relating to detected photon energy based on input signals from the first photon energy resolving spectrometer.

13. The ion implantation system of claim 1, wherein the first photon energy resolving spectrometer is a gamma ray spectrometer.

14. A method of conducting ion implantation operations comprising the operations of:
exciting ions with an atomic number of 1 to 11 and accelerating the ions at an energy of 10 keV to 30 MeV;
detecting photons at a first photon energy resolving spectrometer and transmitting a first signal to a processor;
receiving at the processor the first signal from the first photon energy resolving spectrometer; and
if a threshold is exceeded, processing the first signal to determine a type of photon energy.

15. The method of claim 14, further comprising transmitting an alert signal if the threshold is exceeded.

16. The method of claim 14, further comprising automatically shutting down the ion implantation operations if the threshold is exceeded.

17. The method of claim 14, wherein the photons are at an energy of 100 eV to 20 MeV.

18. The method of claim 14, wherein the photons are at an energy at or exceeding 100 keV to 20 MeV.

19. The method of claim 14, further comprising:
detecting photons at a second photon energy resolving spectrometer and transmitting a second signal to the processor;
receiving at the processor the second signal from the first photon energy resolving spectrometer; and
processing the first signal and second signal to determine a source location of the detected photons.

20. An ion implantation system, comprising:
an ion source that generates ions and produces an ion beam along a beamline, wherein the ions are selected from elements with an atomic number of 11 or less;
a mass analyzer positioned downstream of the ion source that generates a magnetic field;
an ion accelerator downstream of the mass analyzer;
a first photon energy resolving spectrometer associated with a first component of the ion implantation system;
a second photon energy resolving spectrometer associated with a second component of the ion implantation system;
a third photon energy resolving spectrometer associated with a third component of the ion implantation system; and
a processor that is configured to receive input signals from the first, second, and third photon energy resolving spectrometers; process the input signals to identify detected photon energy as known or unknown photon energy; and transmit an alert to a display and/or shutdown the ion implantation system if a threshold of unknown or particular known photon energy is identified;
wherein the processor is configured to process input signals from the first, second, and third photon energy resolving spectrometers to identify a source location of detected photon energy.
